(19) United States
(12) Patent Application Publication
(10) Pub. No.: US 2025/0125276 A1
(43) Pub. Date: Apr. 17, 2025

(54) PACKAGE SUBSTRATE, SEMICONDUCTOR DEVICE, AND METHOD FOR FORMING PACKAGE SUBSTRATE

(71) Applicant: AP MEMORY TECHNOLOGY CORPORATION, HSINCHU COUNTY (TW)

(72) Inventors: RU-YI CAI, HSINCHU COUNTY (TW); KEE-WEI CHUNG, HSINCHU COUNTY (TW); HAN FANG CHENG, HSINCHU COUNTY (TW)

(21) Appl. No.: 18/583,156

(22) Filed: Feb. 21, 2024

Related U.S. Application Data
(60) Provisional application No. 63/590,521, filed on Oct. 16, 2023.

(51) Int. Cl. H01L 23/538; H01L 21/56; H01L 23/00; H01L 23/48; H01L 25/065; H10B 12/00; H10B 80/00

(52) U.S. Cl. CPC H01L 23/5389; H01L 21/56; H01L 23/481; H01L 23/5383; H01L 24/32; H01L 24/83; H01L 24/94; H01L 25/0657; H10B 12/00; H10B 80/00; H01L 2224/32137; H01L 2224/32145; H01L 2224/83; H01L 2224/94

(57) ABSTRACT

A package substrate includes a first dielectric layer, a second dielectric layer and a core layer. The first dielectric layer includes first electrical interconnect. The second dielectric layer includes second electrical interconnect. The core layer is situated between the first dielectric layer and the second dielectric layer, and includes a plurality of semiconductor dies stacked one above another between the first dielectric layer and the second dielectric layer. A first semiconductor die of the semiconductor dies is a capacitor die electrically connected to the first electrical interconnect of the first dielectric layer.

### PRIORITY CLAIM AND CROSS-REFERENCE

The present application claims priority to U.S. Provisional Patent Application No. 63/590,521, filed on Oct. 16, 2023, which is incorporated by reference herein in its entirety.

### BACKGROUND

The present disclosure relates to package substrates, and more particularly, to a package substrate having embedded capacitor dies, a semiconductor device and a method for forming a package substrate.

Due to the miniaturization of logic components (e.g. circuit components of a logic integrated circuit (IC)) with technological advancements, their operating voltages decrease, leading to a smaller tolerance for voltage variations. For instance, assuming a voltage tolerance range of 10% of the rated value, a supply voltage of 3.3 volts allows a variation space of ±0.3 volts, while a supply voltage of 0.7 volts merely leaves a variation space of ±0.07 volts. However, delivering voltage to logic components usually involves transmitting electrical power over long traces on a circuit board, causing significant voltage fluctuations. This, in turn, diminishes the stability and performance of logic components. Thus, there is a need in the art for an improved design to reduce the adverse effects resulting from power transmission.

### SUMMARY

The described embodiments provide a package substrate having embedded capacitor dies, a semiconductor device and a method for forming a package substrate.

Some embodiments described herein may include a package substrate. The package substrate includes a first dielectric layer, a second dielectric layer and a core layer. The first dielectric layer includes first electrical interconnect. The second dielectric layer includes second electrical interconnect. The core layer is situated between the first dielectric layer and the second dielectric layer, and includes a plurality of semiconductor dies stacked one above another between the first dielectric layer and the second dielectric layer. A first semiconductor die of the semiconductor dies is a capacitor die electrically connected to the first electrical interconnect of the first dielectric layer.

Some embodiments described herein may include a semiconductor device. The semiconductor device includes a package substrate and a semiconductor chip. The package substrate has a core layer. The core layer includes an embedded capacitor device. The embedded capacitor device includes a plurality of semiconductor dies and a plurality of adhesive layers. The semiconductor dies are stacked one above another. A first semiconductor die of the semiconductor dies is a capacitor die with exposed terminal electrodes. The adhesive layers are alternately stacked with the semiconductor dies. Each adhesive layer is bonded to two semiconductor dies on opposite sides of the adhesive layer respectively. The semiconductor chip is arranged at a first side the package substrate, and is electrically connected to the embedded capacitive device.

Some embodiments described herein may include a method of forming a package substrate. The method includes: bonding a first semiconductor die and a second semiconductor die to form a semiconductor capacitor stack, wherein at least one of the first semiconductor die and the second semiconductor die is a capacitor die; embedding the semiconductor capacitor stack into a core layer of the package substrate; and forming a first dielectric layer and a second dielectric layer on opposite sides of the core layer, respectively, wherein electrical interconnect of the first dielectric layer is electrically connected to the capacitor die.

With the use of the proposed substrate structure, the package substrate not only can integrate high-performance logic devices with multiple peripheral devices, but also can provide sufficient mechanical strength and efficient power management.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an implementation of a package substrate in accordance with some embodiments.

FIG. 2 is a diagram illustrating an exemplary package substrate in accordance with some embodiments of the present disclosure.

FIG. 3 is a diagram illustrating an implementation of the package substrate shown in FIG. 2 in accordance with some embodiments of the present disclosure.

FIG. 4 is a diagram illustrating another implementation of the package substrate shown in FIG. 2 in accordance with some embodiments of the present disclosure.

FIG. 5 is a diagram illustrating another implementation of the package substrate shown in FIG. 2 in accordance with some embodiments of the present disclosure.

FIG. 6 is a diagram illustrating another implementation of the package substrate shown in FIG. 2 in accordance with some embodiments of the present disclosure.

FIG. 7 is a diagram illustrating another implementation of the package substrate shown in FIG. 2 in accordance with some embodiments of the present disclosure.

FIG. 8 is a flow chart of an exemplary method for forming a package substrate in accordance with some embodiments of the present disclosure.

FIG. 9 is a diagram illustrating an implementation of combination of the semiconductor dies shown in FIG. 3 in accordance with some embodiments of the present disclosure.

FIG. 10 is a diagram illustrating an implementation of formation of the semiconductor capacitor stack shown in FIG. 3 in accordance with some embodiments of the present disclosure.

FIG. 11 is a diagram illustrating an implementation of dicing a wafer stack for forming the semiconductor capacitor stack shown in FIG. 3 in accordance with some embodiments of the present disclosure.

FIG. 12 is a diagram illustrating another implementation of dicing a wafer stack for forming the semiconductor capacitor stack shown in FIG. 3 in accordance with some embodiments of the present disclosure.

FIG. 13 is a diagram illustrating an implementation of embedding of the semiconductor capacitor device into the core layer shown in FIG. 3 in accordance with some embodiments of the present disclosure.

FIG. 14 is a diagram illustrating another implementation of the package substrate shown in FIG. 2 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

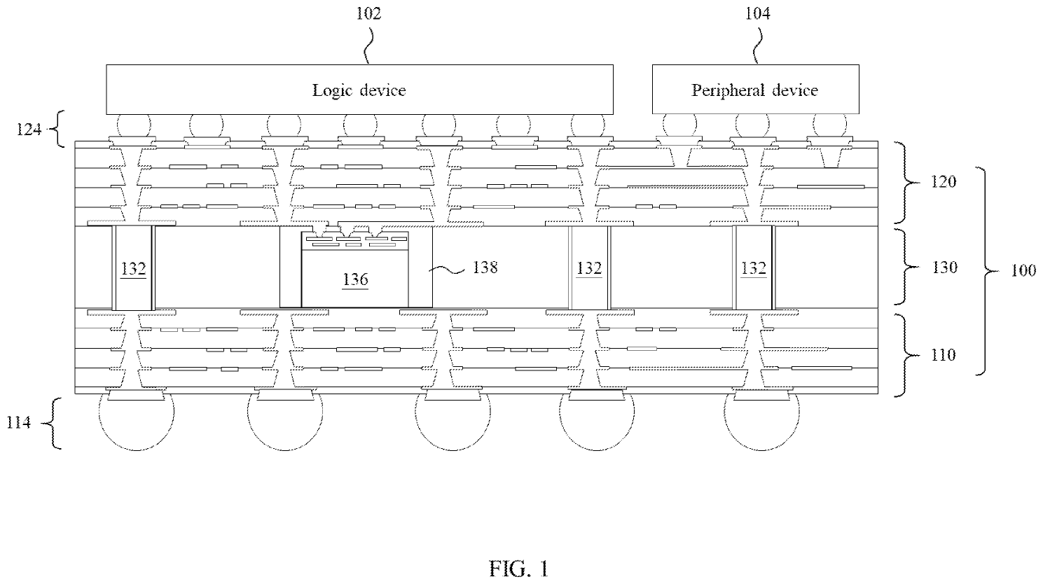

To effectively manage power consumption and improve overall performance in the integrated circuit (IC), heterogeneous integration is proposed to integrate multiple chips or devices on a shared substrate. Referring to FIG. 1, a logic device 102 and a peripheral device 104 can be mounted on the same package substrate 100 to reduce energy loss in long-distance signal transmission. The logic device 102 can be, but is not limited to, a central processing unit (CPU) chip, a graphic processing unit (GPU) chip, a general-purpose computing on graphics processing units (GPGPU) chip, an application processor (AP) chip, a controller chip, or other forms of logic devices/chips. The peripheral device 104 can be, but is not limited to, a memory chip, a system on a chip (SoC), a video chip, an audio chip, a radio frequency (RF) chip, a power management chip, or other types of peripheral devices/chips. As the logic device 102 and the peripheral device 104 are integrated on the same substrate, their proximity allows for increased signal transmission speed and reduced energy consumption.

In the example of FIG. 1, the package substrate 100 comprises a dielectric layer 110, a dielectric layer 120 and a core layer 130. The dielectric layer 110 has a multilayered internal structure and includes electrical interconnect, which can be implemented using metal sub-layers, metal traces, and/or vias. The bump structure 114 formed below the dielectric layer 110 can serve as contact points for interconnection. For example, the dielectric layer 110 can be electrically connected to a printed circuit board (PCB) (not shown) via the bump structure 114. Similarly, the dielectric layer 120 has a multilayered internal structure and includes electrical interconnect, which can be implemented using metal sub-layers, metal traces, and/or vias. The dielectric layer 120 can be electrically connected to the logic device 102 and peripheral devices 104 via bump structure 124.

The core layer 130 includes a plurality of conductive structures 132, and a capacitor die 136. The conductive structures 132 are arranged to provide conductive paths between respective electrical interconnect structures of the dielectric layers 110 and 120. Each conductive structure 132 can be implemented using a plated through-hole (PTH). The capacitor die 136, embedded within a cavity 138 of the core layer 130, can be a semiconductor die that is manufactured and separated from a wafer. The capacitor die 136 contains numerous capacitor structures that include electrode and dielectric structures formed by semiconductor manufacturing processes, thereby providing a larger capacitor surface area and higher capacitance. By way of example but not limitation, the capacitor die 136 can be a trench capacitor die with multiple trench capacitor structures (e.g. multiple trench metal-insulator-metal (MIM) capacitors).

The capacitor die 136 is arranged to store electrical energy and provide the stored electrical energy to the logic device 102, thereby maintaining power stability of the logic device 102. For example, the capacitor die 136 can receive and store electrical energy through the electrical interconnect of the dielectric layer 110 and the bump structure 114, and provide the stored electrical energy to the logic device 102 through the electrical interconnect of the dielectric layer 120 and the bump structure 124. Compared to the energy transmission path from a power source on a printed circuit board (not shown) to the logic device 102, the energy transmission path between the capacitor die 136 and the logic device 102 is significantly shorter when the logic device 102 is placed on the package substrate 100 having the capacitor die 136. Thus, the package substrate 100 can effectively reduce energy losses, and increase power integration and system stability.

For high-end products (e.g., artificial intelligence (AI) produces, high-performance computing (HPC) products, 5G communication applications) that require high computational power or multiple functionalities, a logic device will be used to control more peripheral devices, resulting in an increase in substrate area for heterogeneous integration. For example, in a case where the package substrate 100 is used to integrate one logic device 102 and three peripheral devices 104, the area of the package substrate 100 can be represented by SA. When the package substrate 100 is used to integrate one logic device 102 and six peripheral devices 104, the area of the package substrate 100 may require 4×SA. As the substrate area increases, the thickness of the core layer would need to increase to provide sufficient mechanical support. Additionally, in a case where the logic device 102 is a high-end semiconductor chip (e.g. a GPU or CPU chip with high computational performance), a dielectric layer of the package substrate 100 may need to be thicker to accommodate more metal routing counts, which may require further increase in the thickness of core layer 130 to provide sufficient mechanical support. However, when the thickness of the core layer 130 increases, the capacitor die 136 may be separated from the dielectric layer, making it difficult for the capacitor die 136 to store electrical energy through the dielectric layer or provide electrical energy to the logic device 102 through the dielectric layer.

The present disclosure describes exemplary package substrates, each of which includes a core layer having multiple semiconductor dies stacked on top of each other. At least one of the semiconductor dies is a capacitor die. The package substrate has a thickness greater than that of a single semiconductor die, thus providing sufficient mechanical support. For example, the thickness of the core layer can be substantially equal to the overall thickness of the stacked semiconductor dies. In some embodiments, adjacent semiconductor dies can be bonded using an adhesive layer, such as glue, polymer adhesive or photosensitive adhesive. In some embodiments, at least one semiconductor die (e.g. a capacitor die) can be electrically connected to a logic device placed on the package substrate via electrical interconnect. In some embodiments, the package substrate can be placed on a printed circuit board, and at least one semiconductor die (e.g. a capacitor die) can store electrical energy provided by a power source on the printed circuit board via electrical interconnect. In some embodiments, at least one semiconductor die can be a dummy die, which can be electrically isolated from the electroconductive structures of the package substrate.

The present disclosure further describes exemplary methods for forming a package substrate. The exemplary method can form multiple semiconductor dies stacked one above another (including at least one capacitor die) in a core layer of the package substrate. In addition, the present disclosure describes exemplary semiconductor devices, each of which includes a package substrate and a semiconductor chip formed on the package substrate. The package substrate includes a capacitor device that is embedded into a core layer of the package substrate. The capacitor device includes a semiconductor die stack, in which adjacent semiconductor dies can be bonded using an adhesive layer, such as glue, polymer adhesive or photosensitive adhesive. In some embodiments, adjacent semiconductor dies can be electrically connected to each other via a conductive structure (e.g. a through-substrate via (TSV) structure). The conductive structure can penetrate through the adhesive layer between adjacent semiconductor dies. The proposed structures and methods not only can enable the heterogeneous integration of HPC logic devices with multiple peripheral devices on a package substrate, but also can provide sufficient mechanical strength to support multiple devices/chips on the package substrate.

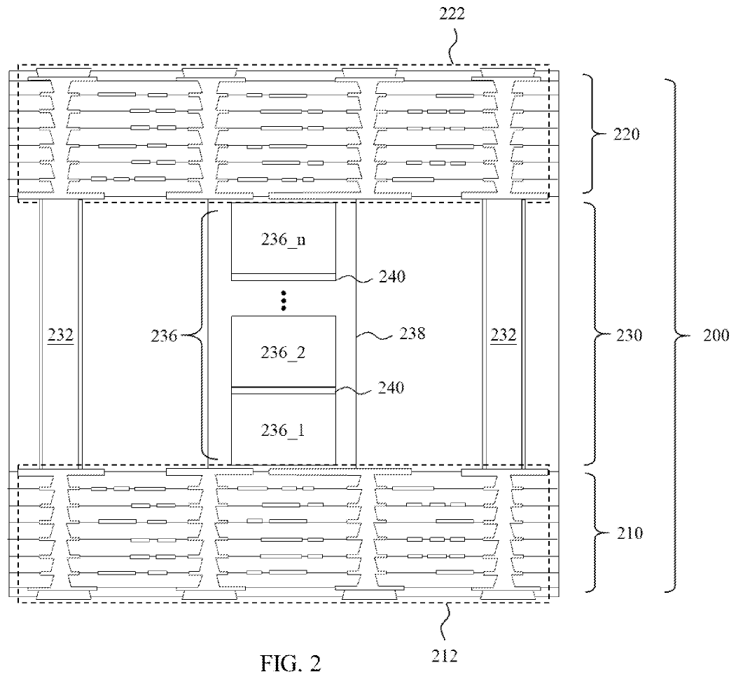

FIG. 2 is a diagram illustrating an exemplary package substrate in accordance with some embodiments of the present disclosure. The package substrate 200 includes, but is not limited to, a dielectric layer 210, a dielectric layer 220 and a core layer 230. The dielectric layer 210 includes electrical interconnect 212 that can be implemented using (but not limited to) metal layers, metal traces, and/or vias. Similarly, the dielectric layer 220 includes electrical interconnect 222 that can be implemented using (but not limited to) metal layers, metal traces, and/or vias. In the present embodiment, each of the dielectric layers 210 and 220 can have a multilayered internal structure. For example, the dielectric layer 210/220 can be implemented using Ajinomoto build-up film (ABF), organic materials, or other dielectric structures capable of providing electrical interconnection.

The core layer 230, situated between the dielectric layers 210 and 220, can serve as the primary support layer of the package substrate 200 to provide mechanical strength and support. By way of example but not limitation, the core layer 230 can be filled with glass fiber and resin materials to provide sufficient mechanical support. The core layer 230 may include, but is not limited to, a plurality of conductive structures 232 and a semiconductor capacitor device (also referred to as a capacitor device for brevity) 236. Each conductive structure 232 is arranged to provide a conductive path between the dielectric layers 210 and 220. At least one conductive structure 232 can be implemented using (but not limited to) a plated through-hole (PTH).

The semiconductor capacitor device 236, embedded in the core layer 230, can have a thickness matching that of the core layer 230. In the present embodiment, the semiconductor capacitor device 236 can be located within the cavity 238. The cavity 238 can be filled with filling material to provide mechanical support and protect the semiconductor capacitor device 236. The filling material may be, but is not limited to, silicone gel, silicone resin, or thermally conductive adhesive.

The semiconductor capacitor device 236 includes a plurality of semiconductor dies 236_1 to 236_n (where n is an integer greater than 1) stacked one above another between the dielectric layers 210 and 220. At least one of the semiconductor dies 236_1 to 236_n is a capacitor die. In the present embodiment, two adjacent semiconductor dies can be bonded to each other using a corresponding adhesive layer 240. In other words, the adhesive layers 240 can be alternately stacked with the semiconductor dies 236_1 to 236_n. Each adhesive layer 240 can be implemented using an adhesive film, glue, adhesive, or polymer adhesive. The thickness of the adhesive layer 240 can range from, but is not limited to, 35 to 50 μm.

For example, the semiconductor dies 236_1 to 236_n can be manufactured and separated from n wafers. Each semiconductor die that is configured as a capacitor die have a large number of capacitor structures designed according to power management requirements. At least one wafer can be processed using semiconductor manufacturing technology to form multiple semiconductor capacitor structures with electrodes and dielectric layers. After the n wafers are stacked together using the adhesive layers 240, the stacked wafers can be cut to form multiple semiconductor capacitor devices. As a result, each semiconductor capacitor device can have stacked semiconductor dies.

Note that each semiconductor capacitor structure can be a three-dimensional (3D) capacitor with high charge storage capacity to facilitate effective power management in HPC applications. For example, as the capacitance density is proportional to the dielectric constant and the capacitor surface area, high-k 3D capacitors are employed to enhance the charge storage capacity. In some embodiments, at least one wafer can be processed using a dynamic random-access memory (DRAM) process to form multiple semiconductor capacitor structures. Thus, at least one of the semiconductor dies 236_1 to 236_n can have a plurality of 3D capacitors formed by the DRAM process. The 3D capacitors can be, but are not limited to, cylindrical capacitors, trench capacitors, or pillar capacitors. A semiconductor die can include millions or more of 3D capacitors.

At least one of the semiconductor dies 236_1 to 236_n can be electrically connected to electrical interconnect of a dielectric layer to receive electrical energy provided by a power source on a circuit board (not shown). Additionally or alternatively, at least one of the semiconductor dies 236_1 to 236_n can be electrically connected to electrical interconnect of a dielectric layer to provide the stored electrical energy to devices/chips placed on the dielectric layer. For example, when the semiconductor die 236_n is configured as a capacitor die and electrically connected to the electrical interconnect 222 of the dielectric layer 220, the semiconductor die 236_n can receive and store electrical energy through the electrical interconnect 222, and provide the stored energy to chip(s) placed on dielectric layer 220 (not shown), such as the logic device 102 shown in FIG. 1, through the electrical interconnect 222. Similarly, when the semiconductor die 236_1 is configured as a capacitor die and electrically connected to the electrical interconnect 212 of the dielectric layer 210, the semiconductor die 236_1 can receive and store electrical energy through the electrical interconnect 212, and provide the stored energy to chip(s) placed on the dielectric layer 210 (not shown), such as the logic device 102 shown in in FIG. 1, though the electrical interconnect 212 and the conductive structures 232.

Compared to the transmission path from an external power source (outside the package substrate 200) to a chip on the dielectric layer 220, the transmission path from the semiconductor dies 236_1 to 236_n to the chip on the dielectric layer 220 is shorter. Therefore, using the semiconductor capacitor device 236 embedded within the core layer 230 to provide electrical energy can effectively reduce power supply noise and enhance overall performance. Additionally, by embedding the stacked semiconductor dies 236_1 to 236_n into the core layer 230, the package substrate 200 not only can have sufficient mechanical support for large substrate area applications, but also can provide sufficient energy storage capacity for efficient power management, thereby enhancing system performance.

To facilitate understanding of the present disclosure, some embodiments are given as follows for further description of the proposed substrate structure. Those skilled in the art should understand that other embodiments employing the core layer structure shown in FIG. 2 fall within the scope of the disclosure. Additionally, the proposed substrate structure is described below with reference to the integration of the logic device 102 and multiple peripheral devices (e.g. multiple peripheral devices similar to the peripheral device 104 shown in FIG. 1) on the same substrate for illustrative purposes. Those skilled in the art should appreciate that the proposed substrate structure can be used for the heterogeneous integration of other devices/chips without departing from the scope of the disclosure.

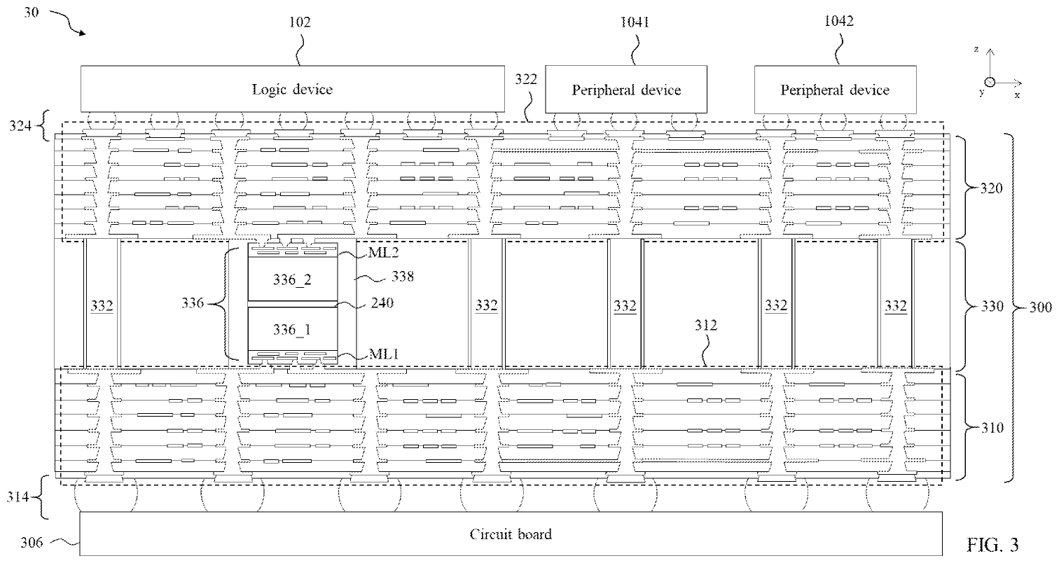

FIG. 3 is a diagram illustrating an exemplary semiconductor device in accordance with some embodiments of the present disclosure. The semiconductor device 30 includes, but is not limited to, the logic device 102 shown in FIG. 1, a package substrate 300 and a circuit board 302 (e.g. a printed circuit board). The package substrate 300 can serve as an implementation of the package substrate 200 shown in FIG. 2. The logic device 102 and the circuit board 302 are arranged at opposite sides of the package substrate 300, respectively.

The area of the package substrate 300 used to accommodate devices (e.g. the cross-sectional area of the package substrate 300 in the xy-plane) is greater than that of the package substrate 100 shown in FIG. 1. Thus, the number of chips/devices placed on the package substrate 300 can be greater than the number of chips/components placed on the package substrate 100 shown in FIG. 1. In the present embodiment, the package substrate 300 is configured to accommodate at least the logic device 102 shown in FIG. 1, and a plurality of peripheral devices 1041 and 1042. The logic device 102 can be, but is not limited to, a semiconductor chip with high computational performance, or a semiconductor chip manufactured using advanced technology nodes. For example, the logic device 102 can be a semiconductor chip that includes a gate-all-around (GAA) transistor structure, which may be manufactured using a 3-nm or 2-nm process. As another example, the logic device 102 can be a semiconductor chip that includes a fin field-effect transistor (FinFET) structure, which may be manufactured using a 3-nm process.

Each of the peripheral devices 1041 and 1042 can be, but are not limited to, a memory chip, an SoC, a video chip, an audio chip, an RF chip, a power management chip, or other types of semiconductor chips. Each peripheral device may be, but is not limited to, a semiconductor chip that includes a GAA transistor structure or a FinFET structure. In addition, the thickness of the package substrate 300 (the dimension of the package substrate 300 in the z direction) is greater than that of the package substrate 100 shown in FIG. 1 to provide greater mechanical support. Note that the number of logic devices and/or peripheral devices shown in FIG. 3 is provided for illustrative purposes, and is not intended to limit the scope of the disclosure.

The package substrate 300 includes a dielectric layer 310, a dielectric layer 320 and a core layer 330, which can serve as embodiments of the dielectric layer 210, the dielectric layer 220 and the core layer 230 shown in FIG. 2, respectively. The bump structure 314 formed below the dielectric layer 310 can serve as contact points for interconnection. For example, the dielectric layer 310 can be electrically connected to the circuit board 306 via the bump structure 314. The dielectric layer 320 can be electrically connected to the logic device 102 and the peripheral devices 1041 and 1042 via the bump structure 324. In the example shown in FIG. 3, the thickness of dielectric layer 320 may be greater than that of dielectric layer 120 shown in FIG. 1 to accommodate more metal routing counts for use by the logic device 102 and the peripheral devices 1041 and 1042. Similarly, the thickness of dielectric layer 310 may be greater than that of dielectric layer 110 shown in FIG. 1 to accommodate more metal routing counts.

The core layer 330 may include a plurality of conductive structures 332 and a semiconductor capacitor device 336. Each conductive structure 332 is arranged to provide a conductive path between the dielectric layers 310 and 320. The semiconductor capacitor device 336 can serve as an embodiment of the semiconductor capacitor device 236 shown in FIG. 2, and include a plurality of semiconductor dies 336_1 and 336_2 stacked between dielectric layers 310 and 320. The semiconductor dies 336_1 and 336_2 can be bonded to each other using the adhesive layer 240. The semiconductor capacitor device 336 has a thickness substantially equal to that of the core layer 330. For example, the semiconductor capacitor device 336 can have a thickness greater than or equal to 1200 μm. As another example, a wafer from which the semiconductor die 336_1/336_2 is separated can undergo thinning before the semiconductor die 336_1/336_2 is cut out. The semiconductor capacitor device 336 can have a thickness greater than or equal to 1000 μm or 800 μm.

In the embodiment shown in FIG. 3, the semiconductor die 336_1 can be a capacitor die that is electrically connected to the electrical interconnect 312 of the dielectric layer 310. For example, the semiconductor die 336_1 may include a conductive layer ML1 (e.g. a metal layer containing top and bottom electrodes) electrically connected to the electrical interconnect 312. The semiconductor die 336_1 can receive and store electrical energy via the conductive layer ML1 and the electrical interconnect 312. Additionally, the semiconductor die 336_1 can provide the stored energy to the logic device 102 via the conductive layer ML1, the electrical interconnect 312, the conductive structure 332, and the electrical interconnect 322.

In addition, the semiconductor die 336_2 can be a capacitor die that is electrically connected to the electrical interconnect 322 of the dielectric layer 320. For example, the semiconductor die 336_2 may include a conductive layer ML2 (e.g. a metal layer containing top and bottom electrodes) electrically connected to the electrical interconnect 322. The semiconductor die 336_2 can receive and store electrical energy via the conductive layer ML2 and the electrical interconnect 322.

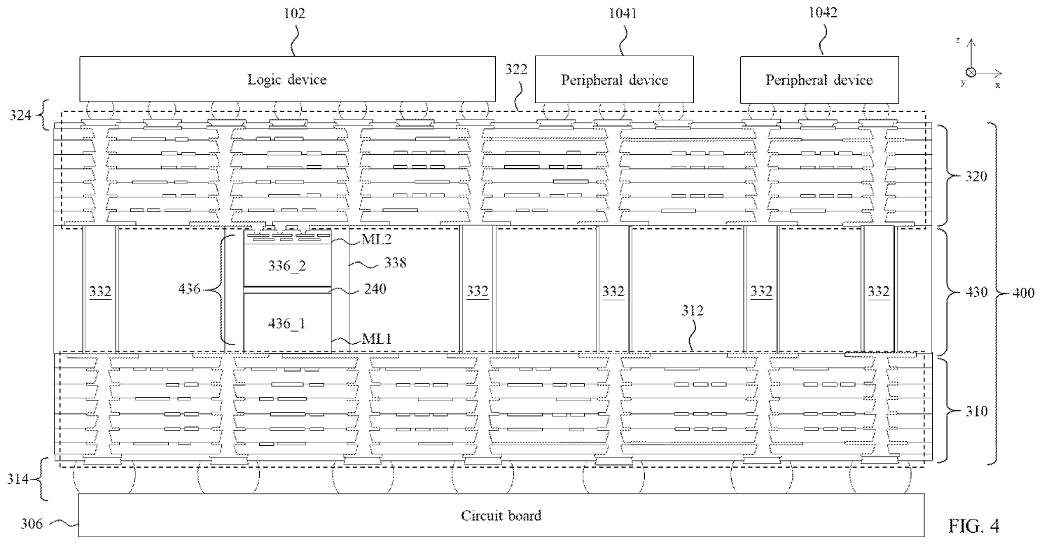

In some embodiments, at least one semiconductor die embedded in the core layer may be a dummy die. Referring to FIG. 4, another implementation of the package substrate 200 shown in FIG. 2 is illustrated in accordance with some embodiments of the present disclosure. The structure of the package substrate 400 is substantially similar/identical to that of the package substrate 300 shown in FIG. 3 except for the semiconductor capacitor device 436. The die stack contained in the semiconductor capacitor device 436 can be implemented using the semiconductor die 336_2 shown in FIG. 3 and a semiconductor die 436_1. The semiconductor die 436_1 is a dummy die bonded to the semiconductor die 336_2 via the adhesive layer 240, and is electrically isolated from external elements (e.g. the semiconductor die 336_2 and the electrical interconnect 312/322). For example, the semiconductor die 436_1 may be a bare die without any functional circuit elements. As another example, the semiconductor die 436_1 may be implemented using the same or similar semiconductor process as the semiconductor die 336_1, except that terminal electrodes (or electrodes that can be electrically connected to external conductive layers, such as the conductive layer ML1 shown in FIG. 3) are not provided in the semiconductor die 436_1. The semiconductor capacitor device 436 can store electrical energy using the semiconductor die 336_2, and provide mechanical support using the semiconductor dies 436_1 and 336_2. The height of the stacked semiconductor dies 436_1 and 336_2 is substantially equal to a thickness of the core layer 430.

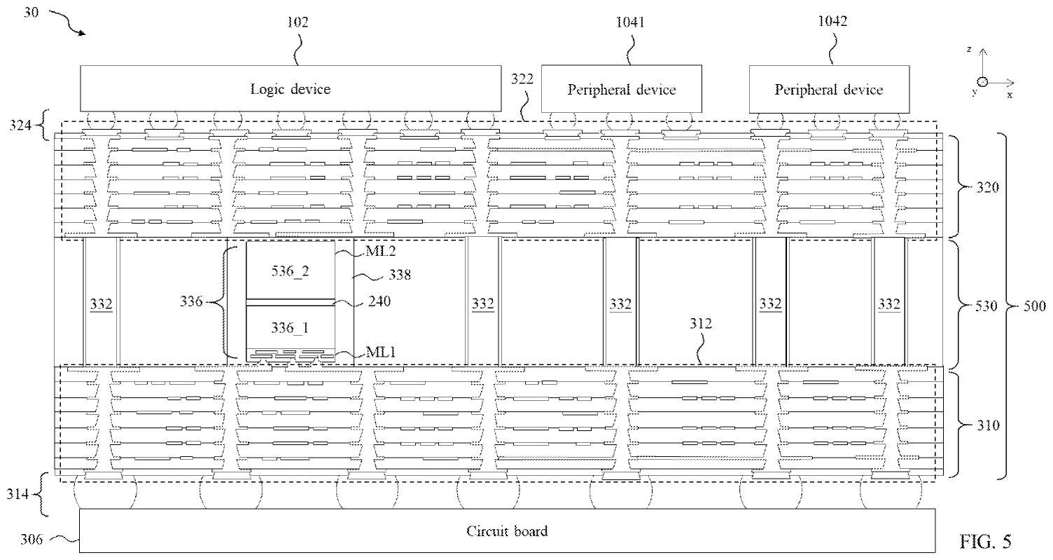

FIG. 5 is a diagram illustrating another implementation of the package substrate 200 shown in FIG. 2 in accordance with some embodiments of the present disclosure. The structure of the package substrate 500 is substantially identical/similar to that of the package substrate 300 shown in FIG. 3 except for the semiconductor capacitor device 536. The die stack contained in the semiconductor capacitor device 536 can be implemented using the semiconductor die 336_1 shown in FIG. 3 and the semiconductor dies 536_2. The semiconductor die 536_2 is a dummy die bonded to the semiconductor die 336_1 via the adhesive layer 240, and is electrically isolated from external elements (e.g. the semiconductor die 336_1 and the electrical interconnect 312/322). For example, the semiconductor die 536_2 may be a bare die without any functional circuit elements. As another example, the semiconductor die 536_2 may be a capacitor die without terminal electrodes. The semiconductor capacitor device 536 can store electrical energy using the semiconductor die 336_1, and provide mechanical support using the semiconductor dies 336_1 and 536_2. The height of the stacked semiconductor dies 336_1 and 536_2 is substantially equal to a thickness of the core layer 530.

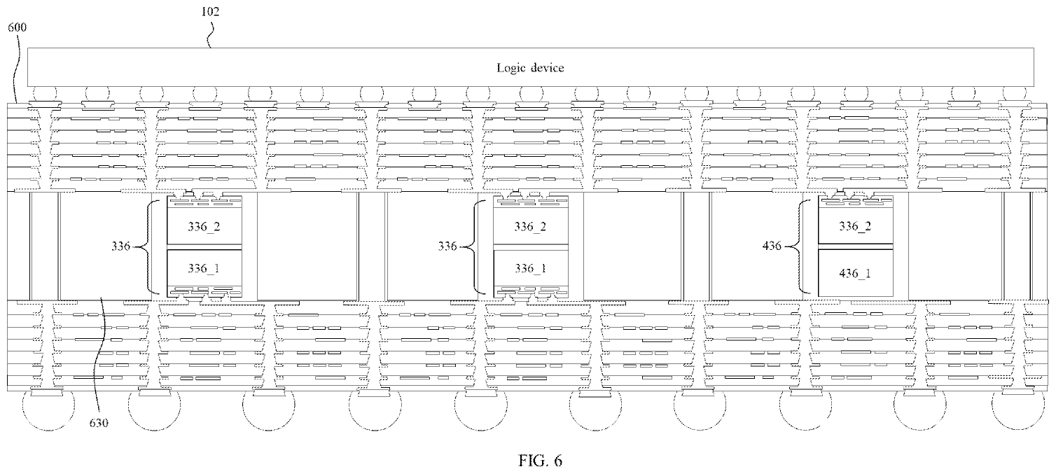

In some embodiments, a plurality of semiconductor capacitor devices can be embedded in the core layer, and each semiconductor capacitor device includes a plurality of semiconductor dies stacked between opposite sides of a core layer. FIG. 6 is a diagram illustrating another implementation of the package substrate 200 shown in FIG. 2 in accordance with some embodiments of the present disclosure. The structure of the package substrate 600 is substantially identical/similar to that of the package substrate 300 shown in FIG. 3 except for the core layer 630. The core layer 630 may be implemented using the semiconductor capacitor device 336 shown in FIG. 3 and the semiconductor capacitor device 436 shown in FIG. 4. With the use of multiple embedded capacitor devices, the package substrate 600 not only can effectively reduce power supply noise, but also can provide sufficient energy storage capacity, thereby enhancing system performance. As those skilled in the art can appreciate the structure of the package substrate 600 after reading the above paragraphs directed to FIG. 1 to FIG. 5, further description is omitted for brevity.

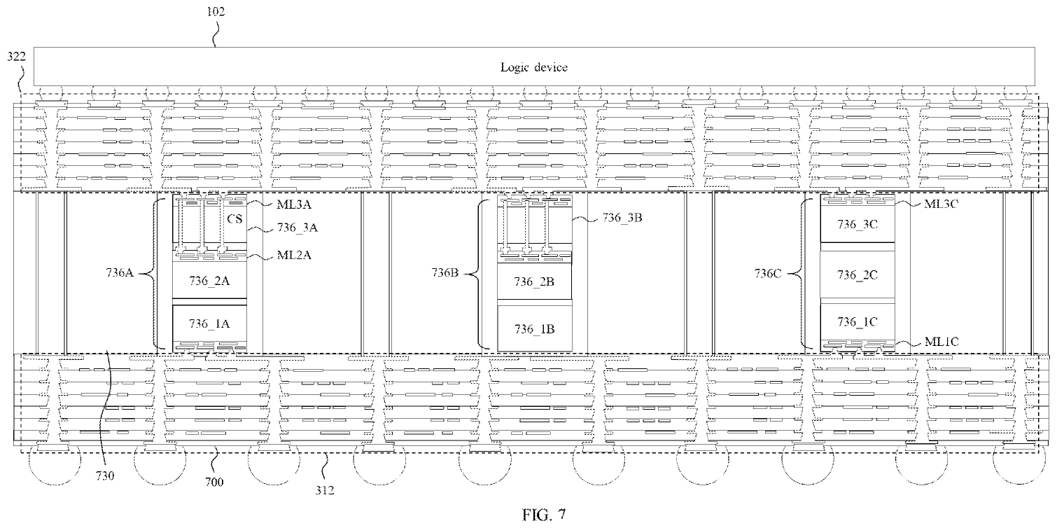

FIG. 7 is a diagram illustrating another implementation of the package substrate 200 shown in FIG. 2 in accordance with some embodiments of the present disclosure. The structure of the package substrate 700 is substantially identical/similar to that of the package substrate 600 shown in FIG. 6 except for the core layer 730. In the present embodiment, the thickness of the core layer 730 may be greater than that of the core layer 630 shown in FIG. 6. For example, the core layer 730 may include a plurality of semiconductor capacitor devices 736A to 736C, which can serve as embodiments of the semiconductor capacitor device 236 shown in FIG. 2. Each semiconductor capacitor device contained in the core layer 730 may have three stacked semiconductor dies, and have a thickness substantially equal to that of the core layer 730.

The semiconductor capacitor device 736A includes a plurality of semiconductor dies 736_1A to 736_3A stacked one above another. The semiconductor die 736_1A is electrically connected to the electrical interconnect 312 of the dielectric layer 310, while the semiconductor dies 736_2A and 736_3A are electrically connected to the electrical interconnect 322 of the dielectric layer 320. In the example shown in FIG. 7, the semiconductor die 736_3A may include a conductive layer ML3A (e.g. a metal layer including top and bottom electrodes) that is electrically connected to the electrical interconnect 322; the semiconductor die 736_2A may include a conductive layer ML2A (e.g. a metal layer including top and bottom electrodes) that is electrically connected to the electrical interconnect 322 through the conductive layer ML3A. For example, the semiconductor die 736_3A may include one or more conductive structures CS (e.g. through-substrate vias (TSVs)) that are electrically connected to the conductive layers ML3A and ML2A. The semiconductor die 736_2A is electrically connected to the electrical interconnect 322 via the conductive layer ML2A, the conductive structures CS and the conductive layer ML3A. Note that vias on the conductive layer ML2A are located in the adhesive layer 240 between the semiconductor dies 736_3A and 736_2A.

The semiconductor capacitor device 736B includes a plurality of semiconductor dies 736_1B to 736_3B stacked one above another. The structure of the semiconductor capacitor device 736B is substantially identical/similar to that of the semiconductor capacitor device 736A except that the semiconductor die 736_1B is implemented as a dummy die. The semiconductor capacitor device 736C includes a plurality of semiconductor dies 736_1C to 736_3C stacked one above another. The semiconductor die 736_1C is electrically connected to the electrical interconnect 312 of the dielectric layer 310; the semiconductor die 736_2C is implemented as a dummy die; the semiconductor die 736_3C is electrically connected to the electrical interconnect 322 of the dielectric layer 320. In the example shown in FIG. 7, the semiconductor die 736_1C may include a conductive layer ML1C that is electrically connected to the electrical interconnect 312; the semiconductor die 736_3C may include a conductive layer ML3C that is electrically connected to the electrical interconnect 322. As those skilled in the art can appreciate the structure of the package substrate 700 after reading the above paragraphs directed to FIG. 1 to FIG. 6, further description is omitted for brevity.

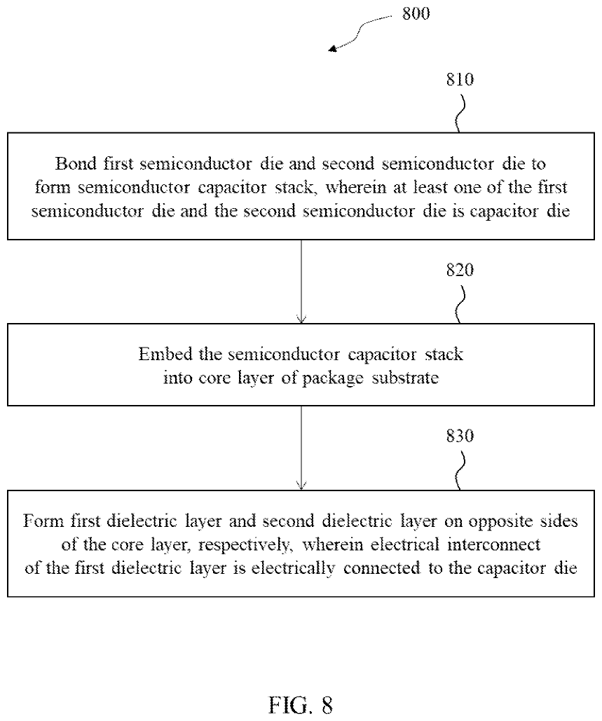

FIG. 8 is a flow chart of an exemplary method for forming a package substrate in accordance with some embodiments of the present disclosure. For illustration purposes, the method 800 is described below with reference to the package substrate 300 shown in FIG. 3. Those skilled in the art will appreciate that the method 800 can be applied to the package substrate 200 shown in FIG. 2, the package substrates 400 to 700 shown in FIG. 4 to FIG. 7, and other package substrates with embedded semiconductor dies without departing from the scope of the disclosure. Additionally, in some embodiments, the method 800 may include other operations.

At operation 810, a first semiconductor die and a second semiconductor die are bonded to form a semiconductor capacitor stack. At least one of the first semiconductor die and the second semiconductor die is a capacitor die, such as a capacitor die with exposed terminal electrodes. For example, the semiconductor dies 336_1 and 336_2 are bonded using the adhesive layer 240 to form a semiconductor capacitor stack (i.e. the semiconductor capacitor device 336).

At operation 820, the semiconductor capacitor stack structure is embedded into a core layer of the package substrate. For example, the semiconductor capacitor device 336 is embedded into the core layer 330.

At operation 830, a first dielectric layer and a second dielectric layer are formed on opposite sides of the core layer, respectively. Electrical interconnect of the first dielectric layer is electrically connected to the capacitor die in the semiconductor capacitor stack. For example, the dielectric layers 310 and 320 are formed on opposite sides of the core layer 330, respectively. The electrical interconnect 312 of the dielectric layer 310 is electrically connected to the semiconductor die 336_1, and the electrical interconnect 322 of the dielectric layer 320 is electrically connected to the semiconductor die 336_2.

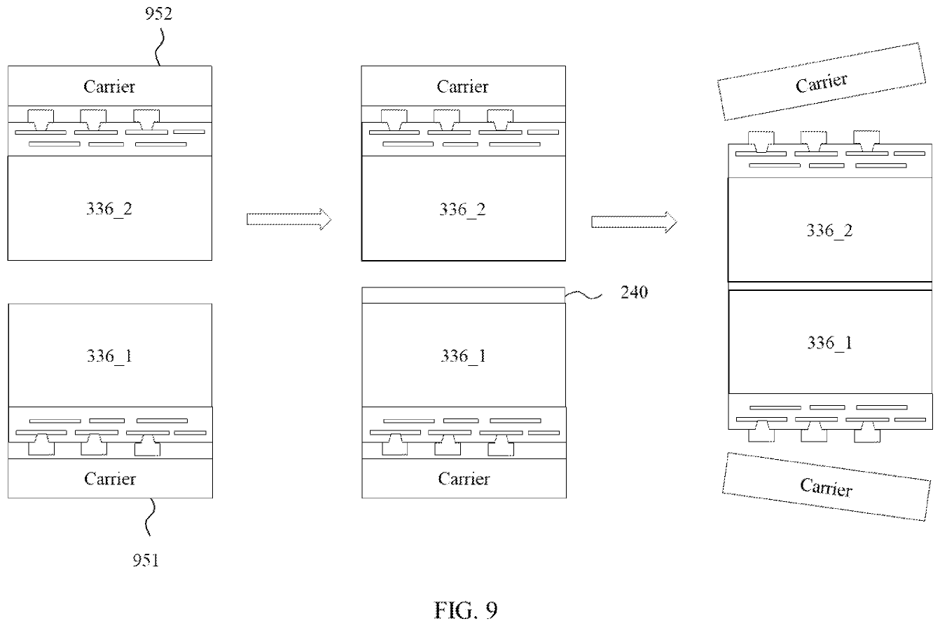

In some embodiments, the first semiconductor die and the second semiconductor die combined at operation 810 may be separated from associated wafers respectively. Referring to FIG. 9, an implementation of combination of the semiconductor dies 336_1 and 336_2 shown in FIG. 3 is illustrated in accordance with some embodiments of the present disclosure. In the embodiment shown in FIG. 9, a first wafer (not shown) having multiple semiconductor dies and a second wafer (not shown) having multiple semiconductor dies are provided. The semiconductor die 336_1 is one of the multiple semiconductor dies contained in the first wafer, and the semiconductor die 336_2 is one of the multiple semiconductor dies contained in the second wafer. Additionally, the first wafer containing the semiconductor die 336_1 and the second wafer containing the semiconductor die 336_2 can be temporarily bonded to carriers 951 and 952, respectively.

Next, the first wafer and the second wafer can be bonded to form a wafer stack, which includes the semiconductor die 336_1 and the semiconductor die 336_2 bonded together by the adhesive layer 240. For example, the adhesive layer 240 can be applied to the first wafer to facilitate the bonding of the first wafer and the second wafer. After the first wafer and the second wafer are bonded to each other, the carriers 951 and 952 can be removed.

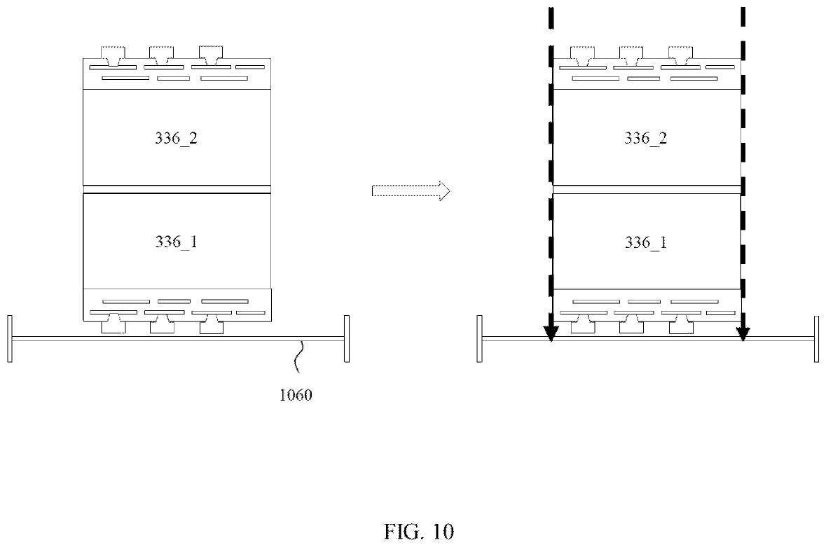

Furthermore, after the first wafer and the second wafer are bonded to each other, the wafer stack can be diced to form a plurality of semiconductor capacitor stacks. Referring to FIG. 10, an implementation of formation of the semiconductor capacitor stack shown in FIG. 3 is illustrated in accordance with some embodiments of the present disclosure. In the embodiment shown in FIG. 10, the wafer stack (including the stacked semiconductor dies 336_1 and 336_2) can be placed on a dicing tape 1060. Wafer dicing (indicated by dashed arrows) can be performed according to positions of scribe lines to form a semiconductor capacitor stack including the semiconductor dies 336_1 and 336_2.

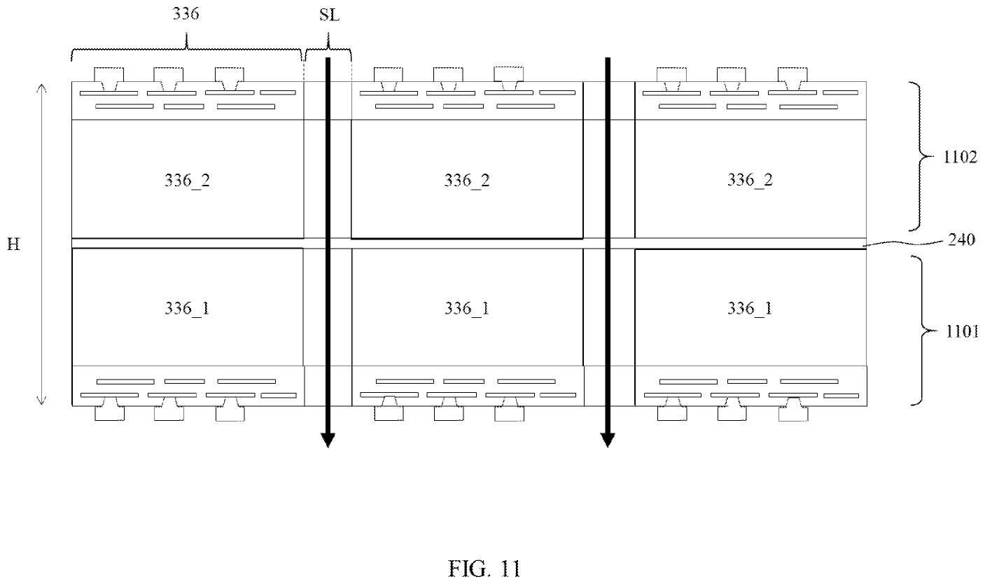

For example, referring to FIG. 11, an implementation of dicing a wafer stack for forming the semiconductor capacitor stack shown in FIG. 3 is illustrated in accordance with some embodiments of the present disclosure. In the embodiment shown in FIG. 11, the wafer 1101 includes the semiconductor dies 336_1, 336_1a and 336_1b, and the wafer 1102 includes the semiconductor dies 336_2, 336_2a and 336_2b. After applying the adhesive layer 240 to the wafer 1101, the wafer 1102 is aligned and stacked with the wafer 1101. Next, wafer dicing can be performed from one side of the wafer 1102 according to positions of scribe lines SL.

In some embodiments, the width of the scribe line SL can range from, but is not limited to, 160 to 300 μm. In some embodiments, the thickness of the core layer (the height H of the stacked wafers 1101 and 1102) can range from, but is not limited to, 800 to 1500 μm. In some embodiments, the ratio of the width of the scribe line SL to the thickness of the core layer can range from, but is not limited to, 5% to 30%.

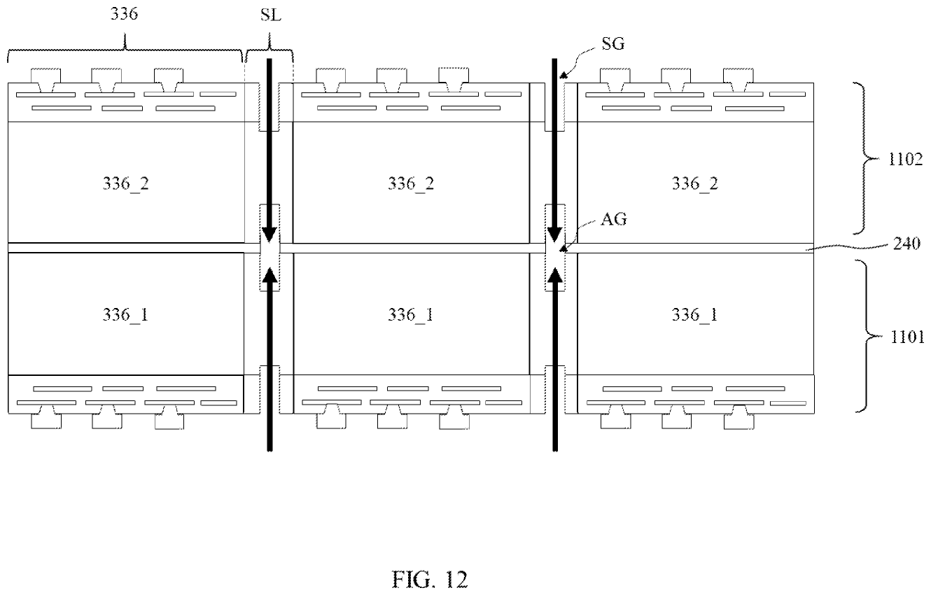

FIG. 12 illustrates another implementation of dicing a wafer stack for forming the semiconductor capacitor stack shown in FIG. 3 in accordance with some embodiments of the present disclosure. In the example shown in FIG. 12, pre-cuts or pre-etching can be performed on the wafer 1101 and wafer 1102 to form grooves (or gaps) SG on the scribe lines SL. After the wafer 1102 is bonded to the wafer 1101 via the adhesive layer 240, a portion of the adhesive layer 240 can be removed according to positions of the grooves SG to thereby form internal gaps AG. For example, the adhesive layer 240 can be photosensitive, allowing removal of adhesive material corresponding to the positions of the grooves SG using exposure lithography techniques. Next, wafer dicing can be performed according to the positions of the scribe lines SL. In the present embodiment, dicing can be performed from both sides of the wafer stack. As the adhesive material corresponding to the dicing positions can be removed beforehand, the adhesive material may not or hardly adhere to the dicing tool during wafer dicing.

In some embodiments, the depth of the groove SG can be less than (but not limited to) 100 μm. In some embodiments, the depth of the gap AG can be less than (but not limited to) 200 μm. In some embodiments, the ratio of the depth of the groove SG to the thickness of the core layer can be less than (but not limited to) 30%. In some embodiments, the ratio of the depth of the gap AG to the thickness of the core layer can be less than (but not limited to) 30%. In some embodiments, the ratio of the width of the scribe line SL to the depth of the groove SG can be less than (but not limited to) 10%.

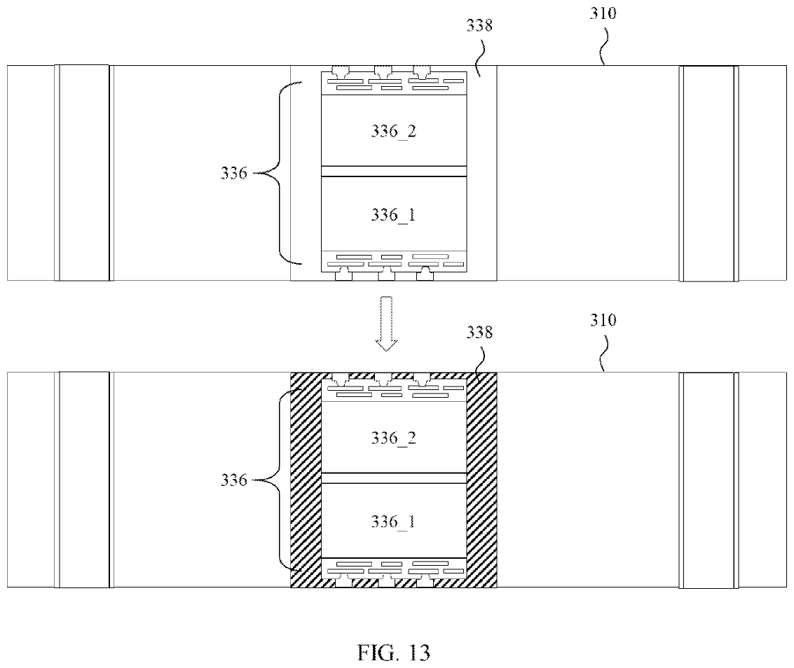

In some embodiments, the embedded semiconductor capacitor stack can be located within a cavity of the core layer. Referring to FIG. 13, an implementation of embedding of the semiconductor capacitor device 336 into the core layer 330 is illustrated in accordance with some embodiments of the present disclosure. In the embodiment shown in FIG. 13, the semiconductor capacitor device 336 can be placed within the cavity 338, followed by filling the cavity 338 with filling material (represented by the slashed area) to provide mechanical support, protection and/or thermal conduction. The filling material may include, but is not limited to, resin, epoxy resin, or other organic materials.

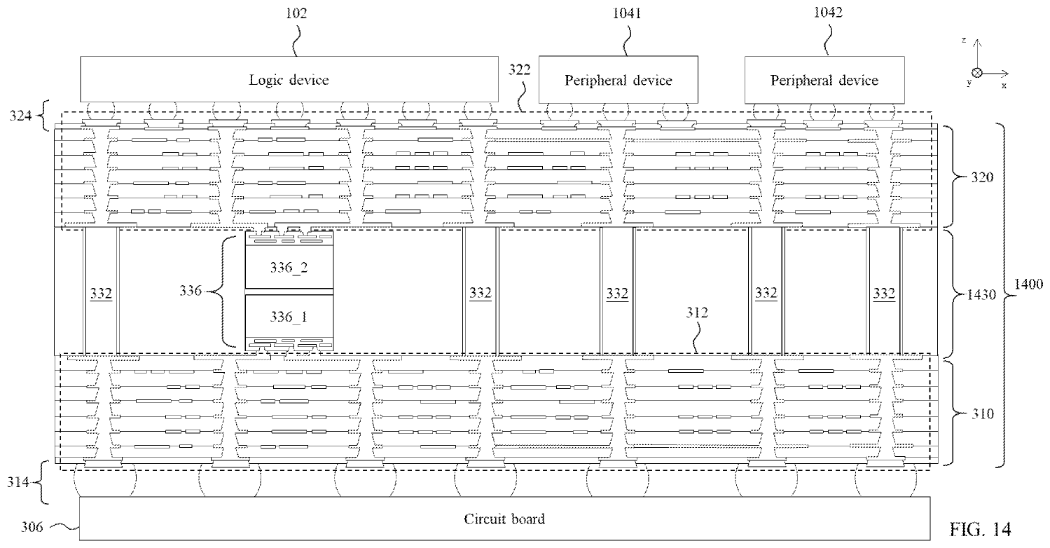

In some embodiments, the embedded semiconductor capacitor stack can be surrounded by material of the core layer. FIG. 14 is a diagram illustrating another implementation of the package substrate 200 shown in FIG. 2 in accordance with some embodiments of the present disclosure. The structure of the package substrate 1400 is substantially identical/similar to that of the package substrate 300 shown in FIG. 3 except for the core layer 1430. In the present embodiment, the semiconductor capacitor device 336 can be surrounded by the filling material (e.g. glass fibers and/or resin material) of the core layer 1430. For example, after the semiconductor capacitor device 336 is cut out from the wafer stack, the semiconductor capacitor device 336 can be placed on a carrier, and glass fibers and resin material can be formed on the carrier to cover the semiconductor capacitor device 336, thus forming the core layer 1430 surrounding the semiconductor capacitor device 336.

As those skilled in the art can appreciate that the method described above for forming a package substrate can be applied to a capacitor stack having with three or more semiconductor dies, repeated description is omitted here for brevity. With the use of the proposed structures and methods, the package substrate not only can integrate high-performance logic devices with multiple peripheral devices, but also can provide sufficient mechanical strength and efficient power management.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package substrate, comprising:
a first dielectric layer comprising first electrical interconnect;
a second dielectric layer comprising second electrical interconnect; and
a core layer, situated between the first dielectric layer and the second dielectric layer, the core layer comprising a plurality of semiconductor dies stacked one above another between the first dielectric layer and the second dielectric layer, wherein a first semiconductor die of the semiconductor dies is a capacitor die electrically connected to the first electrical interconnect of the first dielectric layer.

2. The package substrate of claim 1, wherein a second semiconductor die of the semiconductor dies is a capacitor die electrically connected to the second electrical interconnect of the second dielectric layer.

3. The package substrate of claim 1, wherein a second semiconductor die of the semiconductor dies is a dummy die electrically isolated from the first electrical interconnect of the first dielectric layer and the second electrical interconnect of the second dielectric layer.

4. The package substrate of claim 1, wherein the first semiconductor die comprises a through-substrate via structure, and a second semiconductor die of the semiconductor dies a capacitor die electrically connected to the first electrical interconnect of the first dielectric layer through the through-substrate via structure.

5. The package substrate of claim 1, wherein a thickness of the core layer is greater than or equal to 800 micrometers.

6. The package substrate of claim 1, wherein the semiconductor dies are located within a cavity of the core substrate; the first dielectric layer and the second dielectric layer are formed on opposite sides of the cavity respectively.

7. The package substrate of claim 1, wherein the core layer further comprises:
an adhesive layer, formed between two adjacent semiconductor dies to bond the two adjacent semiconductor dies.

8. The package substrate of claim 7, wherein the adhesive layer comprises polymer adhesive.

9. The package substrate of claim 7, wherein the adhesive layer is photosensitive.

10. The package substrate of claim 1, wherein the core layer further comprises:
a conductive structure, penetrating through the core layer and electrically connected between the first dielectric layer and the second dielectric layer.

11. The package substrate of claim 1, wherein at least one of the semiconductor dies has a plurality of three-dimensional capacitors formed by a dynamic random-access memory (DRAM) process.

12. A semiconductor device, comprising:
a package substrate having a core layer, the core layer comprising an embedded capacitor device, the embedded capacitive device comprising:
a plurality of semiconductor dies stacked one above another, a first semiconductor die of the semiconductor dies is a capacitor die with exposed terminal electrodes; and
a plurality of adhesive layers alternately stacked with the semiconductor dies, wherein each adhesive layer is bonded to two semiconductor dies on opposite sides of the adhesive layer respectively; and
a semiconductor chip, arranged at a first side of the package substrate and electrically connected to the embedded capacitive device.

13. The semiconductor device of claim 12, wherein a second semiconductor die of the semiconductor dies is a dummy die.

14. The semiconductor device of claim 12, wherein the first semiconductor die comprises a through-substrate via structure, and a second semiconductor die of the semiconductor dies a capacitor die electrically connected to the through-substrate via structure.

15. The semiconductor device of claim 12, wherein the adhesive layer comprises polymer adhesive or photosensitive adhesive.

16. The semiconductor device of claim 12, wherein the semiconductor chip comprises a gate-all-around (GAA) transistor structure.

17. The semiconductor device of claim 12, further comprising:
a circuit board, arranged at a second side of the package substrate opposite to the first side, wherein the core layer is located between the first side and the second side.

18. A method of forming a package substrate, comprising:
bonding a first semiconductor die and a second semiconductor die to form a semiconductor capacitor stack, wherein at least one of the first semiconductor die and the second semiconductor die is a capacitor die;
embedding the semiconductor capacitor stack into a core layer of the package substrate; and
forming a first dielectric layer and a second dielectric layer on opposite sides of the core layer, respectively, wherein electrical interconnect of the first dielectric layer is electrically connected to the capacitor die.

19. The method of claim 18, wherein bonding the first semiconductor die and the semiconductor die to form the semiconductor capacitor stack comprises:
providing a first wafer having a plurality of first semiconductor dies;
providing a second wafer having a plurality of second semiconductor dies;
bonding the first wafer and the second wafer to form a wafer stack; and
dicing the wafer stack to form a plurality of semiconductor capacitor stacks, wherein the embedded semiconductor capacitor stack is one of the semiconductor capacitor stack.

20. The method of claim 19, wherein dicing the wafer stack to form the semiconductor capacitor stacks comprises:
forming a groove on each scribe line on the first wafer;
removing a portion of an adhesive layer formed between the first wafer and the second wafer according to each groove position on the first wafer; and
dicing the wafer stack according to each groove position on the first wafer.
